(19) United States
(12) Patent Application Publication
(10) Pub. No.: US 2025/0370509 A1
(43) Pub. Date: Dec. 4, 2025

(54) HOUSING AND ELECTRONIC DEVICE COMPRISING SAME

(71) Applicant: Samsung Electronics Co., Ltd., Suwon-si (KR)

(72) Inventor: Seongyu HWANG, Suwon-si (KR)

(21) Appl. No.: 19/300,080

(22) Filed: Aug. 14, 2025

Related U.S. Application Data
(63) Continuation of application No. PCT/KR2024/002099, filed on Feb. 14, 2024.

(30) Foreign Application Priority Data
Feb. 14, 2023 (KR) 10-2023-0019348
Mar. 2, 2023 (KR) 10-2023-0027924

(51) Int. Cl. G06F 1/16

(52) U.S. Cl. CPC G06F 1/1656

(57) ABSTRACT

An electronic device is provided. The electronic device includes at least one electronic component, a plate forming at least one surface of the electronic device and having at least one recess formed therein, and at least one reinforcing member disposed in the at least one recess, and including a main body having a strength higher than a strength of the plate and a width corresponding to a width of the at least one recess, and at least one protrusion formed along the circumference of the main body, wherein at least a portion of a part where the plate and the at least one reinforcing member face each other includes a friction stir welded area (FSWA).

### CROSS-REFERENCE TO RELATED APPLICATION(S)

This application is a continuation application, claiming priority under 35 U.S.C. § 365 (c), of an International application No. PCT/KR2024/002099, filed on Feb. 14, 2024, which is based on and claims the benefit of a Korean patent application number 10-2023-0019348, filed on Feb. 14, 2023, in the Korean Intellectual Property Office, and of a Korean patent application number 10-2023-0027924, filed on Mar. 2, 2023, in the Korean Intellectual Property Office, the disclosure of each of which is incorporated by reference herein in its entirety.

### BACKGROUND

### 1. Field

The disclosure relates to a housing including heterogeneous materials and an electronic device including the same. More particularly, the disclosure relates to a method for manufacturing a housing included in an electronic device.

### 2. Description of Related Art

Along with the advancement of information and communication technology and semiconductor technology, the proliferation and use of various electronic devices are rapidly increasing. In particular, recent electronic devices have been developed to be portable for communication. Additionally, electronic devices may output stored information as audio or video. As the integration level of electronic devices increases and high-speed, large-capacity wireless communication becomes widespread, various functions may now be integrated into a single electronic device, such as mobile communication terminals or laptop computers. For example, communication functions, entertainment functions like gaming, multimedia functions such as music/video playback, communication and security functions for mobile banking, and schedule management and electronic wallet functionalities are all integrated into one electronic device. These electronic devices are miniaturized so that users may conveniently carry them.

In manufacturing a housing that forms the exterior of an electronic device, a housing including a metal material may be provided to protect various circuit devices included in the electronic device from an external environment. Further, a housing including a non-metal material formed through processes such as injection molding may also be provided to reduce manufacturing costs of the electronic device. According to an embodiment, a housing including both the metal material and the non-metal material, that is, a housing including heterogeneous materials, may be provided.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a method for manufacturing a housing included in an electronic device.

Additional aspects will be set forth in part in the description which follows and, in part, will be apparent from the description, or may be learned by practice of the presented embodiments.

In accordance with an aspect of the disclosure, an electronic device is provided. The electronic device includes at least one electronic component, a plate forming at least one surface of the electronic device and having at least one recess formed therein, and at least one reinforcing member disposed in the at least one recess and including a main body having a strength higher than a strength of the plate and a width corresponding to a width of the at least one recess and at least one protrusion formed along the circumference of the main body, wherein at least a portion of a part where the plate and the at least one reinforcing member face each other includes a friction stir welded area (FSWA).

In accordance with another aspect of the disclosure, a method for manufacturing a housing included in an electronic device is provided. The method includes preparing a plate having at least one recess and at least one reinforcing member, seating the at least one reinforcing member in the at least one recess, performing pre-spot welding to fix at least one protrusion included in the at least one reinforcing member, and performing friction stir welding (FSW) to fix at least a portion of a part where the plate and the at least one reinforcing member face each other.

In accordance with another aspect of the disclosure, a housing in an electronic device is provided. The housing includes a plate having at least one recess formed therein and including a base and an edge surrounding at least a portion of the base, and at least one reinforcing member disposed in the at least one recess and including a main body having a strength higher than a strength of the plate and a width corresponding to a width of the at least one recess and at least one protrusion formed along a periphery of the main body. At least a portion of a part where the plate and the at least one reinforcing member face each other includes an FSWA.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating an electronic device according to an embodiment of the disclosure;

FIG. 2 is a diagram illustrating a plate according to an embodiment of the disclosure;

FIG. 3A is a conceptual diagram illustrating the principle of a rigidity measurement experiment for a plate according to an embodiment of the disclosure;

FIG. 3B is a graph illustrating results of a rigidity measurement experiment for a plate according to an embodiment of the disclosure;

FIG. 4 is a diagram illustrating a plate including heterogeneous materials and a cross-section thereof according to an embodiment of the disclosure;

FIG. 5 is a diagram illustrating a cross-section of a plate according to an embodiment of the disclosure;

FIG. 6A is a perspective view illustrating a state immediately before at least one reinforcing member is seated in at least one recess of a plate according to an embodiment of the disclosure;

FIG. 6B is a diagram illustrating a state after at least one reinforcing member is seated in at least one recess of a plate according to an embodiment of the disclosure;

FIG. 7 is a diagram illustrating a state where at least one reinforcing member including a protrusion is disposed in at least one recess of a base according to an embodiment of the disclosure;

FIG. 8 is a diagram illustrating a plate including a reinforcing member according to an embodiment of the disclosure;

FIG. 9 is a diagram illustrating a process of manufacturing a plate according to an embodiment of the disclosure; and

FIG. 10 is a block diagram illustrating a method for manufacturing a housing included in an electronic device according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In recent years, manufacturing processes and related technologies for electronic devices have become highly advanced, driven by the need for maximized lightness and portability. Additionally, various efforts are being made to reduce the cost of product development and/or production of electronic devices while increasing productivity.

However, for example, the size of an electronic device with a display may gradually increase in response to a user demand for a larger screen. To meet this demand, while simultaneously satisfying the need for lightness and high portability, the electronic device may be provided with a housing or case including heterogeneous materials. For example, a portion of the housing may include a material with a higher strength, such as a metal, while another portion of the housing may include a synthetic resin material which has a lower strength than the metal but is advantageous for reducing an overall weight.

A housing including heterogeneous material was manufactured by bonding two plates located on substantially the same plane, or bonding a portion made of a second material to a housing including a first material through an injection molding process. However, in the method, a part (bonding line) where the two different materials are bonded is exposed or visible from the outside, which may lead to the problem of requiring an additional painting process to visually conceal the bonded part to provide a sense of aesthetic unity.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

According to various embodiments of the disclosure described below, a housing (or case) manufactured in a manner that solves the above problems, and an electronic device including the same may be provided.

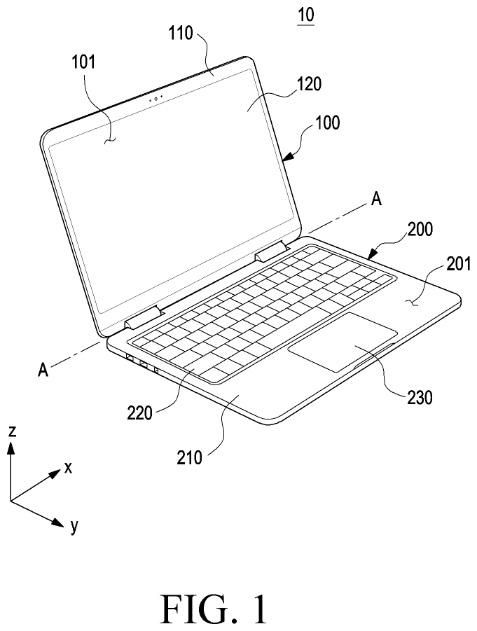

An electronic device according to various embodiments of the disclosure may include, for example, at least one of a smartphone, a tablet, a mobile phone, a video phone, an e-book reader, a desktop computer, a laptop computer, a netbook computer, a workstation, a server, a personal digital assistant (PDA), a portable multimedia player (PMP), an Moving Picture Experts Group 1 (or 2) Audio Layer 3 (MP3) player, a medical device, a camera, or a wearable device. Further, the electronic device according to various embodiments of the disclosure may include a foldable electronic device. A foldable electronic device including a flexible display may also fall into the scope of the disclosure. In FIG. 1 and the following drawings, a laptop computer may be described as an example of the electronic device.

FIG. 1 is a perspective view illustrating an electronic device according to an embodiment of the disclosure.

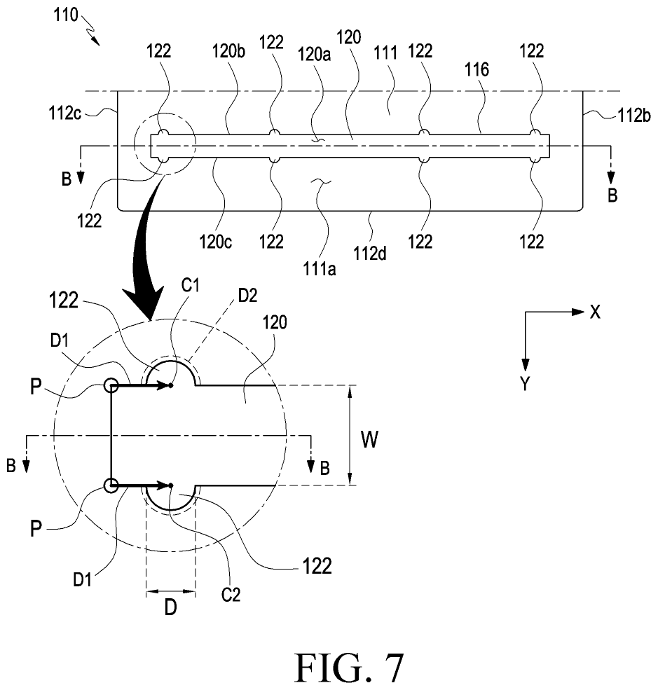

In the disclosure, a directional component X (or X axis), a directional component Y (or Y axis), and a directional component Z (or Z axis) in FIG. 1 may denote mutually orthogonal coordinate axes. In the following description, an A-A axis may be parallel to the directional component X. The length of the electronic device 10 may be defined as a length in a direction parallel to the directional component X, the width of the electronic device 10 may be defined as a width in a direction parallel to the directional component Y, and the thickness or height of the electronic device 10 may be defined as a height in a direction parallel to the directional component Z. In describing directions, when ‘negative/positive (−/+)’ is not stated, it may be interpreted to include both a +direction and a −direction unless otherwise defined. For example, as described later in the description of FIG. 7, when it is said that a protruding direction of a protrusion faces the Y-axis direction, this may be interpreted to include both a +Y-axis direction and a −Y-axis direction. However, it should be noted that the directional components illustrated in various embodiments of the disclosure and the drawings are provided for convenience of description, not specifying the scope of rights or limiting the order.

Referring to FIG. 1, as an example of the electronic device 10 according to an embodiment of the disclosure, a laptop computer may be taken, in which two different housings are pivotably coupled to each other. According to various embodiments, the electronic device 10 may include a first housing 100 including a display 130, and a second housing 200 pivotably coupled to the first housing 100 along a rotation axis in an A-A direction and including at least one input device 220 and 230.

According to an embodiment, the first housing 100 may have the display 130 mounted on a first plate 110 (or upper plate), and when the electronic device 10 is in an open state or unfolded state, a screen of the display 130 may be visible from the outside through a first surface 101 of the first housing 100. According to an embodiment, the second housing 200 may have a keyboard 220 with a plurality of keycaps formed thereon as an input device, mounted on a second plate 210 (or lower plate), and when the electronic device 10 is unfolded, the second plate 210 may be a part where the plurality of keycaps are exposed through a second surface 201 of the second housing 200. On the contrary, when the electronic device 10 is in a closed state or folded state, the display 130 may face the keyboard 220, and the display 130 and keyboard 220 may not be exposed to the outside of the electronic device 10. According to an embodiment, the second housing 200 may further include a pad 230 for a touch input as an input device, in addition to the keyboard 220 with the plurality of keycaps formed thereon.

In the above embodiment, the open and closed states between the first housing 100 and the second housing 200 have been described. In the open state, the first surface 101 of the first housing 100 and the second surface 201 of the second housing 200 may form a predetermined angle greater than approximately 0 degrees and equal to or less than 360 degrees. In the closed state, the first surface 101 of the first housing 100 and the second surface 201 of the second housing 200 may face each other. In a first closed state, the first surface 101 of the first housing 100 and the second surface 201 of the second housing 200 may form an angle of 0 degrees. Herein, the ‘angle’ is merely an example and is not necessarily limited thereto. In each state, they have a different range of angles in consideration of a usage tolerance. For example, when the display is a flexible display, an angle of −10 degrees to +10 degrees may be formed in consideration of the curvature of the flexible display. Various other embodiments are also applicable.

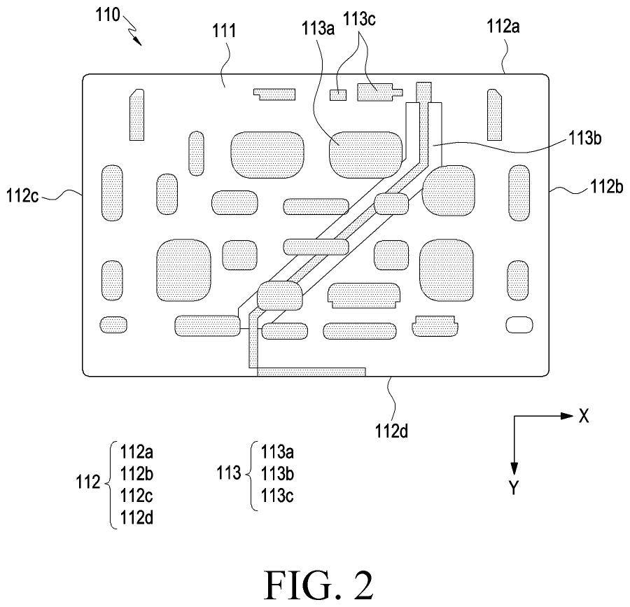

FIG. 2 is a diagram illustrating the plate according to an embodiment of the disclosure.

The plate 110 may be a component forming a portion of the exterior of the electronic device 10 (i.e., a portion of a housing).

When the electronic device 10 is the laptop computer illustrated in FIG. 1, the first housing 100 may include the first surface 101 and the first plate 110, and the second housing 200 may include the second surface 201 and the second plate 210 and be pivotably coupled to the first housing 100. When the electronic device is in the unfolded state, the first surface 101 and the second surface 201 may form a predetermined angle within a range greater than 0 degrees and less than 360 degrees, and when the electronic device is in the folded state, the first surface 101 and the second surface 201 may face each other. In the electronic device 10, the plate 110 in FIG. 2 may correspond to the first plate 110 in FIG. 1 or the second plate 210 in FIG. 1. However, the disclosure is not necessarily limited thereto, and other embodiments are also applicable.

For example, the electronic device 10 may correspond to a tablet. In this case, the housing may include a front plate, a rear plate, and a side member surrounding a space between the front plate and the rear plate, and in the electronic device 10, the plate 110 in FIG. 2 may correspond to the front plate or the rear plate.

Referring to FIG. 2, the plate 110 may include a base 111 and an edge 112 surrounding at least a portion of the base 111. According to an embodiment, the edge 112 may include a first edge 112a and a fourth edge 112d having a first length 11 along a first direction (e.g., X-axis direction), and a second edge 112b and a third edge 112c having a second length 12 smaller than the first length along a second direction (e.g., Y-axis direction) perpendicular to the first direction. As illustrated in the drawing, the plate 110 may have a rectangular shape, and one side of the plate 110 may be formed relatively longer than another side thereof. That is, the plate 110 may include a long side and a short side. For example, the ratio of the long side to the short side of the plate 110 may be approximately 16:9.

In an embodiment, the plate 110 may be formed in a thin form (i.e., a thin plate) and include at least one recess 113. According to an embodiment, the at least one recess 113 may exist in the base 111 in a form that penetrates a portion of the base or decreases the thickness of a portion of the base. According to the embodiment illustrated in FIG. 2, the at least one recess may include a cutting opening 113a for reducing the weight of the plate 110, a wiring mounting opening 113b, and/or a component mounting opening 113c. Although the at least one recess is not separately indicated by a reference numeral, it may be provided as a plurality of recesses as illustrated in FIG. 2. According to the embodiment illustrated in FIG. 2, the at least one recess may be formed, for example, through a machining process (e.g., computerized numerical control (CNC) process) performed in a final stage of a housing manufacturing method.

As illustrated in FIG. 2, for example, when the plate 110 is applied to a relatively small bar-type mobile communication terminal, forming the entire or a substantial portion of the base 111 of a metal material may not significantly affect lightness and portability. However, when the plate 110 is applied to a larger electronic device such as a laptop computer or a tablet, it may significantly reduce lightness and portability. Although manufacturing the base 111 of a synthetic resin may be considered accordingly, the strength of the electronic device is significantly reduced.

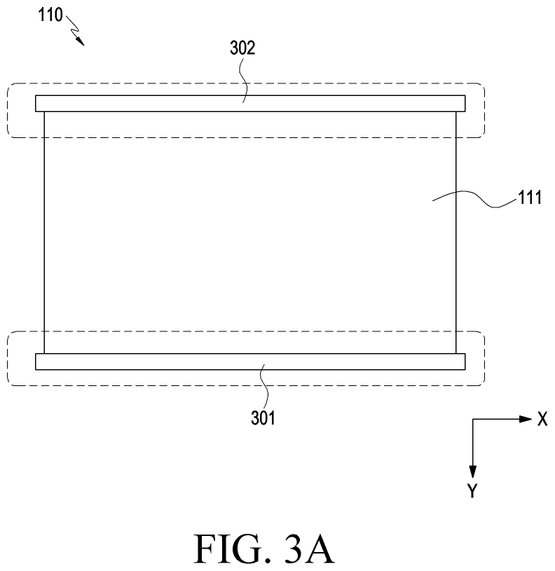

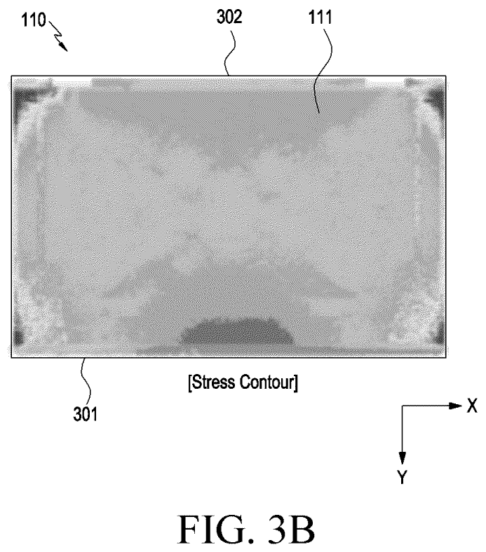

FIG. 3A is a conceptual diagram illustrating the principle of a rigidity measurement experiment for the plate according to an embodiment of the disclosure. FIG. 3B is a diagram illustrating results of a rigidity measurement experiment for the plate according to an embodiment of the disclosure.

FIGS. 3A and 3B may illustrate a preparation process for the rigidity measurement experiment on the plate 110 illustrated in FIG. 2, and simulation results of the experiment.

Referring to FIG. 3A, the rigidity measurement experiment for the plate 110 may be performed by connecting a portion (e.g., the fourth edge 112d) of the plate 110 to a fixer 301 of a measurement device, and connecting another portion (e.g., the first edge 112a) of the plate 110 to a driver 202 of the measurement device. According to an embodiment, when the plate 110 is connected to the measurement device as illustrated in FIG. 3A, repeatedly applying a constant load by the driver 302 may yield simulation results as illustrated in FIG. 3B.

Referring to FIG. 3B, it may be noted from the operation results of the measurement device on the plate 110 that the edges of the plate 110, particularly corner portions of the plate 110, are subjected to high stress relative to the other portions.

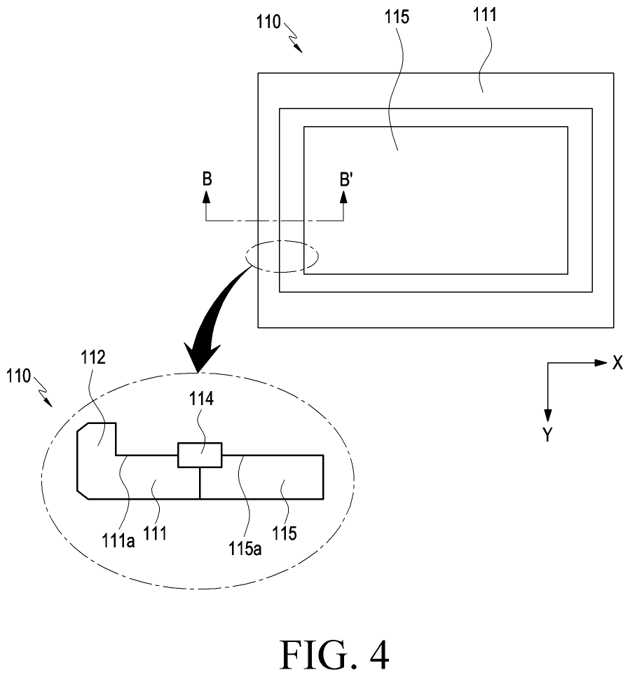

FIG. 4 is a diagram illustrating the plate including heterogeneous materials and its cross-section according to an embodiment of the disclosure.

According to an embodiment, as illustrated in FIG. 4, a plate 110 including a first base 111 and a second base 115 may be provided by referring to the results of the rigidity measurement experiment illustrated in FIGS. 3A and 3B. The second base 115 is a part made of a different material from that of the first base 111, and the plate 110 including the first base 111 and the second base 115 may be formed by welding two different plates or by an injection molding process. In this case, the first base 111 may include a material with a higher strength than the second base 115, or the second base 115 may include a material with a higher strength than the first base 111. For example, when the plate 110 is formed by welding two plates of different materials, the first base 111 and the second base 115 may be disposed on substantially the same plane, and a contact point P1 or bonding line between the first base 111 and the second base 115 may be welded while the sides of the first base 111 and the sides of the second base 115 are in contact with each other. In this case, the welding method may include welding (e.g., fusion welding) in which a base material is melted and attached, pressure-based welding (e.g., pressure welding) in which a base material is plastically deformed and attached, or soldering (e.g., or brazing) in which a molten material (filler metal) is melted and attached.

Referring to FIG. 4, however, the method of welding the contact point P1 or bonding line between the first base 111 and the second base 115 may result in a welding layer 114 formed at a position not deep from a surface 111a of the first base 111 and a surface 115a of the second base 115, thereby causing a problem such as detachment between the first base 111 and the second base 115 or peeling of the welding layer. Moreover, as the welding layer 114 is formed, there may be a design disadvantage in that components should be mounted on the electronic device, avoiding the welding layer 114.

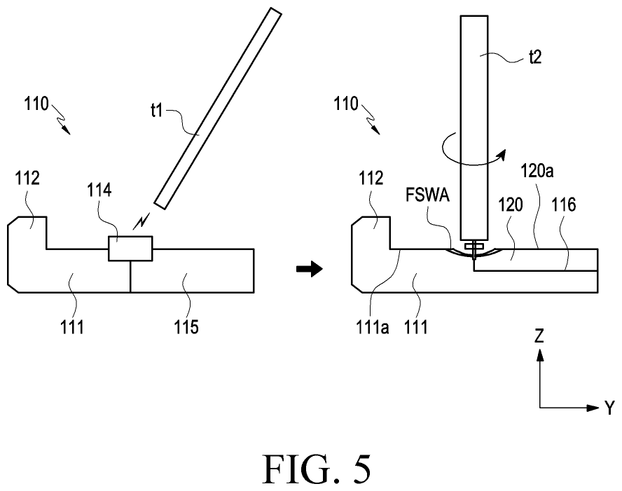

Therefore, the disclosure is intended to provide various embodiments of a housing and an electronic device including the same, which may solve the above-described problems, through the embodiments of FIG. 5 and the following drawings.

FIG. 5 is a diagram illustrating a cross-section of a plate according to an embodiment of the disclosure.

Referring to FIG. 5, the left drawing illustrates the plate 110 formed by facing the sides of the two different bases 111 and 115 and welding the contact point P1 or bonding line between the two different bases 111 and 115, for example, using a welding tool T1 (e.g., an arc welding electrode). For example, the left drawing of FIG. 5 may represent a method of welding two different plates by laser welding, using a laser irradiation device as the welding tool T1. However, this is merely an example to illustrate a method of welding two different plates, and the illustration and description of the left drawing of FIG. 5 do not limit the welding method.

The right drawing of FIG. 5 illustrates a plate 110 on which at least one reinforcing member 120 with a strength higher than that of the base 111 of the plate 110 is located in at least one recess 116 and at least a portion of a part facing the at least one reinforcing member 120 is bonded with the at least one reinforcing member 120 by friction stir welding (FSW).

In the left drawing of FIG. 5, the welding layer 114 that protrudes higher than the surfaces of the two plates may be formed between the two different plates, whereas in the right drawing of FIG. 5, there is no protruding welding layer 114, and a friction stir welded area (FSWA), which is partially collapsed in the thickness direction from the surface of the base 111, is formed. FSW may be a type of pressure welding. FSW may be a method in which a base material is bonded by fixing the base material, and inserting and rotating, in the base material, a portion of a welding tool T2 (e.g., a stir rod) of a harder material than the base material along a bonding portion, thereby generating frictional heat through relative movement of the tool and the base material. According to FSW, due to the frictional heat generated during the rotation of the welding tool T2, elements of a first material included in the base 111 are mixed into the reinforcing member 120, and elements of a second material included in the reinforcing member 120 may be partially mixed into the base 111. At this time, at least some of the elements of the first material included in the base 111 and the elements of the second material included in the reinforcing member 120 may be transformed into a metal alloy.

When a molten material is melted for bonding, product deformation such as detachment or cracking of the protruding welding layer 114 may occur. FSW obviates the need for a separate molten material, prevents cracks that may occur in fusion welding, and causes no deformation, thereby achieving excellent mechanical properties.

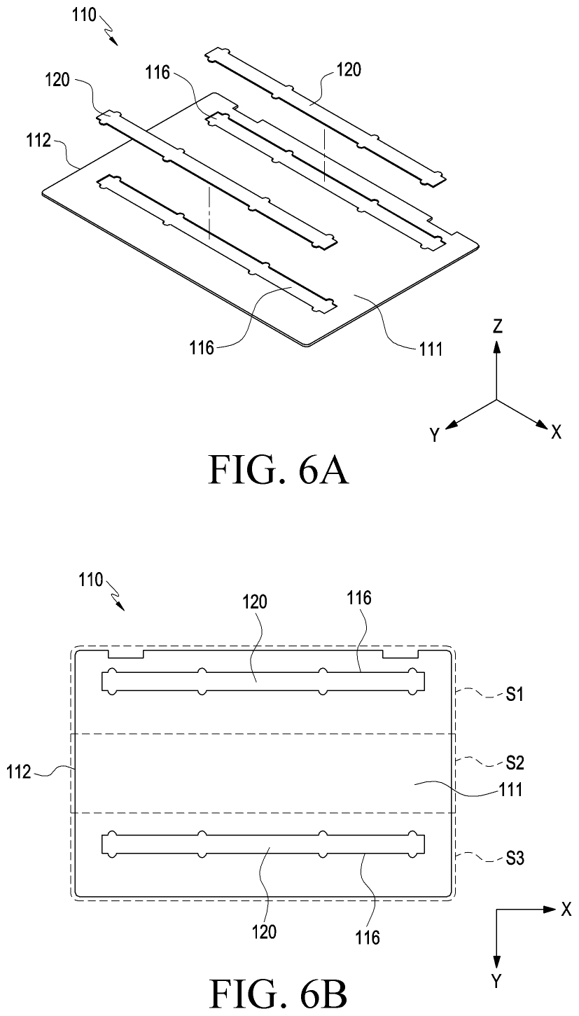

FIG. 6A is a perspective view illustrating a state immediately before at least one reinforcing member is seated in at least one recess of a plate according to an embodiment of the disclosure.

FIG. 6B is a diagram illustrating a state after at least one reinforcing member is seated in at least one recess of a plate according to an embodiment of the disclosure.

According to an embodiment of the disclosure, an electronic device (e.g., the electronic device 10 in FIG. 1) may include a housing (e.g., the first housing 100) including the plate 110, and the plate 110 may include the at least one reinforcing member 120 with at least one protrusion 122.

Referring to FIG. 6A, the at least one reinforcing member 120 may be inserted and disposed in the at least one recess 116 formed in the base 111, and the at least one recess 116 may have a shape corresponding to the at least one reinforcing member 120. In an embodiment, the at least one recess 116 may have a corresponding shape in response to the at least one reinforcing member 120 including the at least one protrusion 122. For example, the at least one reinforcing member 120 may be formed to have a width substantially equal to the width of the at least one recess 116. According to an embodiment, when the at least one reinforcing member 120 is inserted and disposed in the at least one recess 116, the at least one reinforcing member 120 and the at least one recess 116 may be configured to be fitted together. According to an embodiment, the at least one recess 116 may be a component provided separately from the recess 113 described above with reference to FIG. 2. According to an embodiment, the at least one recess 116 may have a groove shape recessed towards the bottom surface of the base 111, and the base 111 may have a larger thickness in a portion where the at least one recess 116 is formed than in a portion where the at least one recess 116 is not formed. As the at least one reinforcing member 120 is inserted and disposed in the at least one recess 116, the rigidity of the plate 110 may be increased.

According to an embodiment, a plurality of recesses 116 may be provided, and the at least one reinforcing member 120 may also be provided in a number corresponding to the number of the at least one recess 116. For example, as illustrated in FIGS. 6A and 6B, two recesses 116 may be provided, and two reinforcing members 120 may be provided correspondingly. However, this is merely an example, and it should be noted that the electronic device 10 and the housing of the electronic device in the disclosure may include more recesses 116 and more reinforcing members 120. The following description will focus on an embodiment in which the electronic device 10 and the housing of the electronic device include two recesses 116 and two reinforcing members 120.

Referring to FIG. 6B, the at least one reinforcing member 120 may be formed at an out-of-center position, spaced apart in the second direction (e.g., Y-axis direction) from an imaginary line (or area) passing through the center of the plate 110. For example, as illustrated in FIG. 6B, when the entire area of the plate 110 is assumed to be divided into, for example, three areas S1, S2, and S3, the at least one reinforcing member 120 may be disposed in the area S1 or S3 excluding the area S2 corresponding to the imaginary line (or area) passing through the center of the plate 110. According to an embodiment, the position and direction where the at least one reinforcing member 120 is disposed, that is, the position and direction where the at least one recess 116 is formed, may be set in consideration of the overall shape of the plate 110. As described before with reference to FIGS. 3A and 3B, the plate 110 is typically a large-area component in a rectangular shape and has a high risk of fracture due to deformation in the vicinity of the edges. Therefore, the at least one recess 116 may be formed in a position and direction that compensate for the risk. The at least one reinforcing member 120 may be disposed parallel to the long sides (e.g., the first edge 112a and the fourth edge 112d) of the plate 110 in the area S1 or S3 excluding the area S2 corresponding to the imaginary line (or area) passing through the center of the plate 110.

With reference to FIG. 7, the configurations of the at least one reinforcing member 120 and the at least one protrusion 122 included in the at least one reinforcing member 120 according to the disclosure will be described in more detail.

FIG. 7 is a diagram illustrating at least one reinforcing member including a protrusion, which is disposed in at least one recess of a base according to an embodiment of the disclosure.

The at least one reinforcing member 120 may include a main body 121 that defines the overall shape of the reinforcing member 120, and the at least one protrusion 122 formed to protrude from the main body 121.

The main body 121 may be formed in the form of an overall thin, long plate and disposed to face a direction parallel to the first direction (e.g., X-axis direction). The protrusion 122 may have a shape protruding in one direction (e.g., the second direction (e.g., Y-axis direction) perpendicular to the first direction (e.g., X-axis direction)) on the same plane as the main body 121. Referring to a cross-section in the right drawing of FIG. 5 and FIG. 7 together, when the at least one reinforcing member 120 is inserted and disposed in the at least one recess 116, a top surface 120a of the reinforcing member 120 including the main body 121 and the protrusion 122 may form substantially the same plane with the top surface 111a of the base 111.

According to an embodiment, while the protrusion 122 is shown in FIG. 7 as having a semicircular shape, the shape of the protrusion 122 is not necessarily limited thereto. According to an embodiment, the protrusion 122 may have a shape including a circle, a semicircle, a triangle, a square, or a polygon with five or more sides.

Referring to FIG. 7, the at least one reinforcing member 120 may include a first side 120b facing the first edge 112a, and a second side 120c facing the fourth edge 112d. A plurality of protrusions 122 may be formed on each of the first side 120b and the second side 120c, at predetermined intervals along the first direction (e.g., X-axis direction). Further, the plurality of protrusions formed on the first side 120b of the at least one reinforcing member 120 may be symmetrically arranged with the plurality of protrusions formed on the second side 120c with respect to an imaginary line B-B passing through the center of the at least one reinforcing member 120 along the first direction. According to an embodiment, the plurality of protrusions 122 formed on the first side 120b of the at least one reinforcing member 120 and the plurality of protrusions 122 formed on the second side 120c of the at least one reinforcing member 120 may have the same diameter D. According to an embodiment, when C1 is the center of a protrusion 122 closest to an end of the at least one reinforcing member 120 among the plurality of protrusions 122 formed on the first side 120b of the at least one reinforcing member 120, and C2 is the center of a protrusion 122 closest to the end of the at least one reinforcing member 120 among the plurality of protrusions 122 formed on the second side 120c of the at least one reinforcing member 120, then C1 and C2 may be disposed at symmetrical positions with respect to the imaginary line passing through the center of the at least one reinforcing member 120.

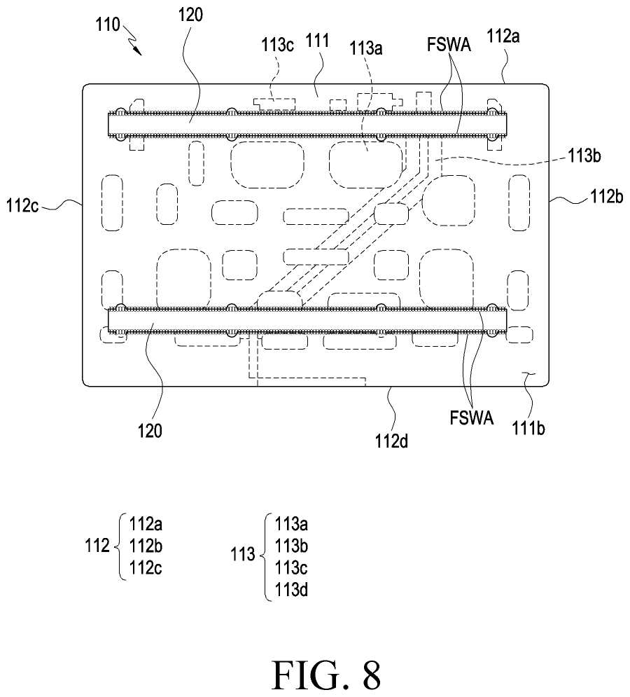

FIG. 8 is a diagram illustrating a plate including at least one reinforcing member according to an embodiment of the disclosure.

Referring to the right drawing of FIG. 5, and FIGS. 7 and 8 together, the electronic device 10 and the housing of the electronic device according to various embodiments of the disclosure may include the plate 110 that includes an FSWA.

According to an embodiment, FSWAs may be formed along the first side 120b and the second side 120c of the at least one reinforcing member 120. For each reinforcing member 120, two FSWAs may be included, spaced apart from each other in a width direction of the reinforcing member 120. According to an embodiment, FSW may be performed linearly along one direction (e.g., X-axis direction) from the end of the at least one reinforcing member 120. FIG. 7 illustrates a point P where FSW starts and a direction D1 in which the FSW is performed. According to an embodiment, a direction in which an FSWA is formed may be perpendicular to the protruding direction of the at least one protrusion 122. For example, the at least one protrusion 122 may protrude in the second direction (e.g., Y-axis direction (+Y-axis direction and −Y-axis direction)) from the first side 120b and the second side 120c of the at least one reinforcing member 120, respectively, and the second direction may be perpendicular to the first direction (e.g., X-axis direction) in which the FSWA is formed.

According to an embodiment, the at least one protrusion 122 may be a component provided to increase a fastening force between the at least one reinforcing member 120 and the base 111, when FSW is performed. According to an embodiment, a plurality of protrusions 122 may be provided along the direction D1 in which the FSW is performed. In this case, as the number of the at least one protrusion 122 is greater and/or the area of the at least one protrusion 122 is wider, the fastening force of the plate 110 on which the FSW has been performed may be proportionally improved. Additionally, as the widths W of the at least one reinforcing member 120 and the at least one recess 116 are smaller, the fastening force of the plate 110 on which the FSW has been performed may be proportionally improved. Therefore, for a greater fastening force of the plate 110 involving FSW, it may be desirable that the reinforcing member 120 is formed to be as narrow as possible in width and the number of the at least one protrusion 122 is increased. Alternatively or additionally, it may be desirable to widen the area of the at least one protrusion 122 as much as possible.

According to an embodiment, at least a portion of the part where the at least one protrusion 122 of the at least one reinforcing member 120 and the base 111 of the plate 110 face each other may include a spot welded area. According to an embodiment, prior to performing FSW, welding may be performed on the at least one protrusion 122. In this case, the welding on the at least one protrusion 122 may be spot welding. Further, in the sense that it is performed prior to FSW, the welding on the at least one protrusion 122 may be referred to as pre-spot welding. As welding is performed on the at least one protrusion 122 prior to FSW, the at least one reinforcing member 120 may be fixed without detaching from the base 111 during the FSW. Referring to FIG. 7, the pre-spot welding on the at least one protrusion 122 may be implemented by performing welding in a perimeter direction D2 of the at least one protrusion 122. As described above, pre-spot welding may include welding using an electrode, or laser welding. According to an embodiment, the pre-spot welding may be performed in various welding methods other than FSW. According to an embodiment, when pre-spot welding is performed on the at least one protrusion 122, the at least one protrusion 122 and the base 111 with their sides facing each other may be bonded.

According to an embodiment, an FSWA may be formed by penetrating through the at least one protrusion 122. Referring to FIGS. 7 and 8 together, it is shown that the FSWA formed from the starting point P passes through the center (e.g., C1 and/or C2) of the at least one protrusion 122.

As described before with reference to FIG. 5, according to FSW, due to the frictional heat generated during the rotation of the welding tool T2, the elements of the first material included in the base 111 are mixed into the at least one reinforcing member 120, and the elements of the second material included in the at least one reinforcing member 120 may be partially mixed into the base 111, while at least some of them may be transformed into a metal alloy. That is, according to the disclosure, the plate 110 with an increased strength may be provided by plastically deforming the two different materials through FSW. According to an embodiment, the at least one protrusion 122 may be formed at a position spaced apart from the starting point P1 of the FSWA by a predetermined distance. For example, when the at least one protrusion 122 is located at the starting point P1, the different materials may not be mixed together during FSW, which may be disadvantageous for achieving a desired fastening force.

FIG. 8 illustrates a plate on which both pre-spot welding and FSW of the disclosure have been performed according to an embodiment of the disclosure. According to an embodiment, a final product with the recesses 113 illustrated in the drawing may be manufactured through separate post-processing after FSW.

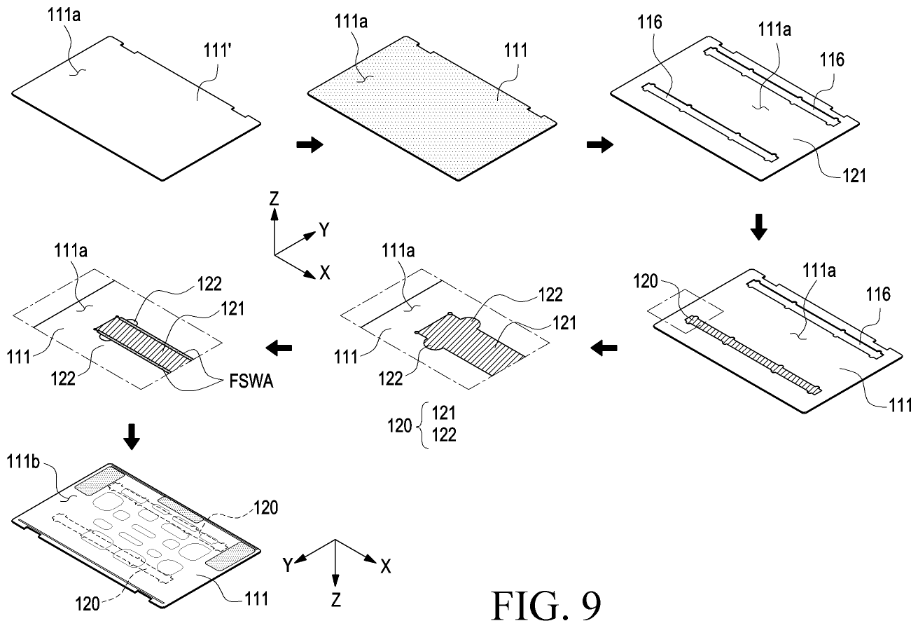

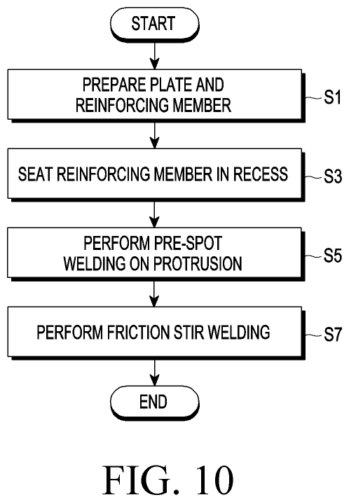

FIG. 9 is a diagram illustrating a process of manufacturing a plate according to an embodiment of the disclosure. FIG. 10 is a block diagram illustrating a method for manufacturing a housing included in an electronic device according to an embodiment of the disclosure.

According to an embodiment, a method for manufacturing a housing included in an electronic device may be provided. The method for manufacturing the housing may refer to a method for manufacturing the plate 110 illustrated in FIGS. 1, 2, 3A, 3B, 4, 5, 6A, 6B, 7, and 8.

Referring to FIG. 10, the method for manufacturing the housing may include operation 1010 for preparing the plate 110 having the at least one recess 116 formed therein and the at least one reinforcing member 120. Further, the method may include operation 1020 for seating the at least one reinforcing member 120 in the at least one recess 116. The method may include operation 1030 for performing pre-spot welding to fix the at least one protrusion 122 included in the at least one reinforcing member 120. The method may include operation 1040 for performing FSW to fix at least a portion of a part where the plate 110 and the at least one reinforcing member 120 face each other.

The method for manufacturing the housing will be described in detail with reference to FIGS. 9 and 10 together.

Regarding operation 1010 for preparing the plate and the reinforcing member S1, a base material 111′ of the plate may be formed to a desired size through an extrusion and/or forging process. The base material 111′ of the plate may be a component including a first material with a lower strength than a second material of the at least one reinforcing member 120 described later. For example, the base material 111′ of the plate may include a synthetic resin and/or a low-strength metal such as aluminum.

According to an embodiment, the base 111 of the plate may be manufactured by processing the base material 111′ of the plate. For example, the base 111 may be obtained by performing pre-processing such as a CNC process and a flattening process on the base material 111′ of the plate.

According to an embodiment, the base 111 may perform a process of processing the at least one recess 116 for seating the at least one reinforcing member 120 therein. The at least one recess 116 may be formed at a predetermined position in consideration of various factors such as the size and shape of the plate, a subsequent process, and/or the positions and shapes of electronic components to be arranged according to the subsequent process. The at least one recess 116 may be, for example, a hole (or groove) of a predetermined depth. The operation for preparing the at least one reinforcing member 120 may be performed before or after the operation for preparing the base 111 of the plate 110. Alternatively, the operation for preparing the at least one reinforcing member 120 may be performed simultaneously with the operation for preparing the base 111 of the plate 110.

Regarding operation 1020 for seating the at least one reinforcing member 120 in the at least one recess 116, the at least one reinforcing member 120 may be seated in the at least one recess 116 according to an embodiment. The at least one reinforcing member 120 may be formed of the second material having higher rigidity than the base 111, which may correspond to, for example, a high-rigidity material such as stainless steel.

According to an embodiment, pre-spot welding may be performed on the at least one protrusion 122 of the at least one reinforcing member 120 seated in the at least one recess 116. The at least one reinforcing member 120 may be prevented from detaching in a subsequent process by bonding the at least one protrusion 122 with a portion of the base 111 surrounding the protrusion 122.

According to an embodiment, after performing pre-spot welding on the at least one reinforcing member 120 seated in the at least one recess 116, FSW may be performed. The FSW may be performed along a longitudinal direction (e.g., X-axis direction) of the at least one reinforcing member 120. Through this process, an FSWA may be permanently formed at and around a bonded portion between the base 111 and the reinforcing member 120, thereby significantly improving the rigidity of the plate 110.

For the plate 110 including the FSWA, a final product may be manufactured by performing, for example, post-processing such as a CNC process, a flattening process, and/or an anodizing process according to an embodiment.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively,” as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to an embodiment, the electronic device 10 may be provided, which includes the plate 110 forming at least one surface of the electronic device and having the at least one recess 113 formed therein, and the at least one reinforcing member 120 disposed in the at least one recess 113, and including the main body 121 having a strength higher than a strength of the plate 110 and a width corresponding to a width of the at least one recess, and the at least one protrusion 122 formed along a periphery of the main body. At least a portion of a part where the plate and the at least one reinforcing member face each other includes an friction stir welded area (FSWA).

According to an embodiment, the electronic device may include the first housing 100 including the first surface 101 and the first plate 110, and the second housing 200 including the second surface 201 and the second plate 210 and pivotably coupled to the first housing 100. The plate 110 may correspond to the first plate or the second plate.

According to an embodiment, the electronic device may include a housing that includes a front plate, a rear plate, and a side member surrounding a space between the front plate and the rear plate. The plate 110 may correspond to the front plate or the rear plate.

According to an embodiment, the plate may include the base 111, the first edge 112a and the fourth edge 112d having a first length along a first direction, and the second edge 112b and the third edge 112c having a second length smaller than the first length along a second direction perpendicular to the first direction. The main body may have a thin and elongated shape extending in a direction parallel to the first direction.

According to an embodiment, the at least one reinforcing member may be formed at an out-of-center position, spaced apart in the second direction from an imaginary line passing through a center of the plate.

According to an embodiment, the at least one reinforcing member may include the first side 120b facing the first edge 112a and the second side 120c facing the fourth edge 112d, and the at least one protrusion may include a plurality of protrusions formed on the first side and the second side, respectively, spaced apart by a predetermined interval along the first direction.

According to an embodiment, the plurality of protrusions formed on the first side may be symmetrically arranged with the plurality of protrusions formed on the second side with respect to an imaginary line passing through a center of the reinforcing member along the first direction.

According to an embodiment, when the at least one reinforcing member is disposed in the at least one recess, a surface of the at least one reinforcing member and a surface of the base included in the plate may be located on substantially the same plane.

According to an embodiment, a direction in which the FSWA is formed may be perpendicular to a protruding direction of the at least one protrusion.

According to an embodiment, the FSWA may be formed by penetrating through the at least one protrusion.

According to an embodiment, at least a portion of a part where the at least one protrusion and the plate face each other may include a spot welded area.

According to an embodiment, the at least one protrusion may have a shape including a circle, a semicircle, a triangle, a square, or a polygon with five or more sides.

According to an embodiment, the at least one protrusion may be formed at a position spaced apart from a starting point of the FSWA by a predetermined distance.

According to an embodiment, the plate may include aluminum, and the at least one reinforcing member may include stainless steel.

According to an embodiment, a method for manufacturing a housing included in an electronic device may be provided, which includes preparing S1 a plate having at least one recess and at least one reinforcing member, seating S3 the at least one reinforcing member in the at least one recess, performing operation 1030 pre-spot welding to fix at least one protrusion included in the at least one reinforcing member, and performing operation 1040 friction stir welding (FSW) to fix at least a portion of a part where the plate and the at least one reinforcing member face each other.

According to an embodiment of the disclosure, a housing of an electronic device may be provided, which includes the plate 110 having the at least one recess 113 formed therein and including the base and the edge 112 surrounding at least a portion of the base 111, and the at least one reinforcing member 120 disposed in the at least one recess 113, and including the main body 121 having a strength higher than a strength of the plate 110 and a width corresponding to a width of the at least one recess, and the at least one protrusion 122 formed along a periphery of the main body. At least a portion of a part where the plate and the at least one reinforcing member face each other includes an FSWA.

According to an embodiment, the edge 112 may include the first edge 112a and the fourth edge 112d having a first length along a first direction, and the second edge 112b and the third edge 112c having a second length smaller than the first length along a second direction perpendicular to the first direction, the at least one reinforcing member may include the first side 120b facing the first edge 112a and the second side 120c facing the fourth edge 112d, and the at least one protrusion may include a plurality of protrusions formed on the first side and the second side, respectively, spaced apart by a predetermined interval along the first direction.

According to an embodiment, the plurality of protrusions formed on the first side may be symmetrically arranged with the plurality of protrusions formed on the second side with respect to an imaginary line passing through a center of the reinforcing member along the first direction.

According to an embodiment, the FSWA may extend in a direction perpendicular to a protruding direction of the at least one protrusion.

According to an embodiment, at least a portion of a part where the at least one protrusion and the plate face each other may include a spot welded area.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
at least one electronic component;
a plate forming at least one surface of the electronic device and having at least one recess formed therein; and
at least one reinforcing member disposed in the at least one recess, and including a main body having a strength higher than a strength of the plate and a width corresponding to a width of the at least one recess, and at least one protrusion formed along a periphery of the main body,
wherein at least a portion of a part where the plate and the at least one reinforcing member face each other includes a friction stir welded area (FSWA).

2. The electronic device of claim 1, comprising:
a first housing including a first surface and a first plate; and
a second housing including a second surface and a second plate, and pivotably coupled to the first housing,
wherein the plate is the first plate or the second plate.

3. The electronic device of claim 1, comprising:
a housing that includes a front plate, a rear plate, and a side member surrounding a space between the front plate and the rear plate,
wherein the plate is the front plate or the rear plate.

4. The electronic device of claim 1,
wherein the plate includes:
a base,
a first edge and a fourth edge having a first length along a first direction, and
a second edge and a third edge having a second length smaller than the first length along a second direction perpendicular to the first direction, and
wherein the main body has a thin and elongated shape extending in a direction parallel to the first direction.

5. The electronic device of claim 4, wherein the at least one reinforcing member is formed at an out-of-center position, spaced apart in the second direction from an imaginary line passing through a center of the plate.

6. The electronic device of claim 4,
wherein the at least one reinforcing member includes:
a first side facing the first edge, and
a second side facing the fourth edge, and
wherein the at least one protrusion includes a plurality of protrusions formed on the first side and the second side, respectively, spaced apart by a predetermined interval along the first direction.

7. The electronic device of claim 6, wherein the plurality of protrusions formed on the first side are symmetrically arranged with the plurality of protrusions formed on the second side with respect to an imaginary line passing through a center of the reinforcing member along the first direction.

8. The electronic device of claim 1, wherein, when the at least one reinforcing member is disposed in the at least one recess, a surface of the at least one reinforcing member and a surface of a base included in the plate are located on substantially the same plane.

9. The electronic device of claim 1, wherein the FSWA extends in a direction perpendicular to a protruding direction of the at least one protrusion.

10. The electronic device of claim 1, wherein the FSWA is formed by penetrating through the at least one protrusion.

11. The electronic device of claim 1, wherein at least a portion of a part where the at least one protrusion and the plate face each other includes a spot welded area.

12. The electronic device of claim 1, wherein the at least one protrusion has a shape including a circle, a semicircle, a triangle, a square, or a polygon with five or more sides.

13. The electronic device of claim 1, wherein the at least one protrusion is formed at a position spaced apart from a starting point of the FSWA by a predetermined distance.

14. The electronic device of claim 1,
wherein the plate includes aluminum, and
wherein the at least one reinforcing member includes stainless steel.

15. A method for manufacturing a housing included in an electronic device, the method comprising:
preparing a plate having at least one recess and at least one reinforcing member;
seating the at least one reinforcing member in the at least one recess;
performing pre-spot welding to fix at least one protrusion included in the at least one reinforcing member; and
performing friction stir welding (FSW) to fix at least a portion of a part where the plate and the at least one reinforcing member face each other.

16. A housing of an electronic device, comprising
a plate having at least one recess formed therein and including a base and an edge surrounding at least a portion of the base, and
the at least one reinforcing member disposed in the at least one recess, and including the main body having a strength higher than a strength of the plate and a width corresponding to a width of the at least one recess, and at least one protrusion formed along a periphery of the main body,
wherein at least a portion of a part of the housing where the plate and the at least one reinforcing member face each other includes an FSWA.

17. The housing of claim 16,
wherein the edge includes a first edge and a fourth edge having a first length along a first direction, and a second edge and a third edge having a second length smaller than the first length along a second direction perpendicular to the first direction, and
wherein the at least one reinforcing member may include a first side facing the first edge and a second side facing the fourth edge, and the at least one protrusion may include a plurality of protrusions formed on the first side and the second side, respectively, spaced apart by a predetermined interval along the first direction.

18. The housing of claim 17, wherein the plurality of protrusions formed on the first side is symmetrically arranged with the plurality of protrusions formed on the second side with respect to an imaginary line passing through a center of the reinforcing member along the first direction.

19. The housing of claim 16, wherein the FSWA extends in a direction perpendicular to a protruding direction of the at least one protrusion.

20. The housing of claim 16, wherein at least a portion of a part of the housing where the at least one protrusion and the plate face each other includes a spot welded area.
